(19) United States
(12) Patent Application Publication
(10) Pub. No.: US 2014/0360572 A1
(43) Pub. Date: Dec. 11, 2014

(54) SOLAR CELL APPARATUS AND METHOD OF FABRICATING THE SAME

(71) Applicant: LG INNOTEK CO., LTD., Seoul (KR)

(72) Inventors: Se Han Kwon, Seoul (KR); Chi Hong Park, Seoul (KR); Do Won Bae, Seoul (KR)

(21) Appl. No.: 14/361,180

(22) PCT Filed: Nov. 26, 2012
(86) PCT No.: PCT/KR2012/010047

§ 371 Date: May 28, 2014

(30) Foreign Application Priority Data
Nov. 28, 2011 (KR) 10-2011-0125438

(51) Int. Cl. H01L 31/0224

(52) U.S. Cl. CPC H01L 31/022433
USPC 136/256

(57) ABSTRACT

Disclosed are a solar cell apparatus and a method of fabricating the same. The solar cell apparatus includes a substrate, a back electrode layer on the substrate, a light absorbing layer on the back electrode layer, a front electrode layer on the light absorbing layer, a bus bar provided beside the light absorbing layer while being connected to the back electrode layer, and a conductive part surrounding the bus bar. The method includes forming a back electrode layer on a substrate, forming a bus bar on the back electrode layer, forming a light absorbing layer beside the bus bar on the back electrode layer, and forming a front electrode layer on the light absorbing layer. A conductive part surrounds the bus bar in the step of forming the bus bar.

### TECHNICAL FIELD

The embodiment relates to a solar cell apparatus and a method of fabricating the same.

### BACKGROUND ART

Recently, as energy consumption is increased, a solar cell apparatus has been developed to convert solar energy into electrical energy.

In particular, a CIGS-based solar cell, which is a P-N hetero junction apparatus having a substrate structure including a glass substrate, a metallic back electrode layer, a P type CIGS-based light absorbing layer, a high resistance buffer layer, and an N type window layer, has been extensively used.

Various studies and researches have been performed to improve electrical characteristics of the solar cell apparatus, such as low resistance and high transmittance.

Meanwhile, since a bus bar provided on a solar cell has an intrinsic luster, an additional cover process is required, and the process time may be prolonged due to the cover process. In addition, to bond the bus bar to the solar cell, a soldering process is required, which increases the fabricating cost.

### DISCLOSURE OF INVENTION

### Technical Problem

The embodiment provides a solar cell apparatus capable of representing improved power generation efficiency and a method of fabricating the same.

### Solution to Problem

According to the embodiment, there is provided a solar cell apparatus comprising a substrate, a back electrode layer on the substrate, a light absorbing layer on the back electrode layer, a front electrode layer on the light absorbing layer, a bus bar provided beside the light absorbing layer while being connected to the back electrode layer, and a conductive part surrounding the bus bar.

According to the embodiment, there is provided a method of fabricating a solar cell apparatus. The method includes forming a back electrode layer on a substrate, forming a bus bar on the back electrode layer, forming a light absorbing layer beside the bus bar on the back electrode layer, and forming a front electrode layer on the light absorbing layer. A conductive part surrounds the bus bar in the step of forming the bus bar.

### Advantageous Effects of Invention

As described above, the solar cell apparatus of the embodiment includes the conductive part surrounding the bus bar. The conductive part is located on the bottom surface of the bus bar, so that the bus bar can be bonded to the back electrode layer.

In addition, the conductive part is located on the top surface of the bus bar to cover the intrinsic luster of the bus bar. In other words, an additional tape to cover the intrinsic luster of the bus bar can be omitted.

Through the method of fabricating the solar cell apparatus of the embodiment, the conventional soldering process to bond the bus bar can be omitted, so that the manufacturing cost can be reduced. In addition, the processes to cover the intrinsic luster of the bus bar can be omitted, so that the process time can be reduced.

### BRIEF DESCRIPTION OF DRAWINGS

FIG. 1 is a plan view showing a solar cell apparatus according to the embodiment;

FIG. 2 is a sectional view taken along line A-A′ of FIGS. 1; and

FIGS. 3 to 13 are sectional views showing the fabricating process of the solar cell apparatus according to the embodiment.

### MODE FOR THE INVENTION

In the description of the embodiments, it will be understood that when a layer (film), a region, a pattern, or a structure is referred to as being “on” or “under” another substrate, another layer (film), another region, another pad or another pattern, it can be “directly” or “indirectly” on the other substrate, the other layer (film), the other region, the other pad or the other pattern, or one or more intervening layers may also be present. Such a position of the layer has been described with reference to the drawings.

The thickness and size of each layer (or film), each region, each pattern, or each structure shown in the drawings may be exaggerated, omitted or schematically drawn for the purpose of convenience or clarity. In addition, the size of the layer (or film), the region, the pattern, or the structure does not utterly reflect an actual size.

Hereinafter, the embodiment will be described with reference to accompanying drawings in detail.

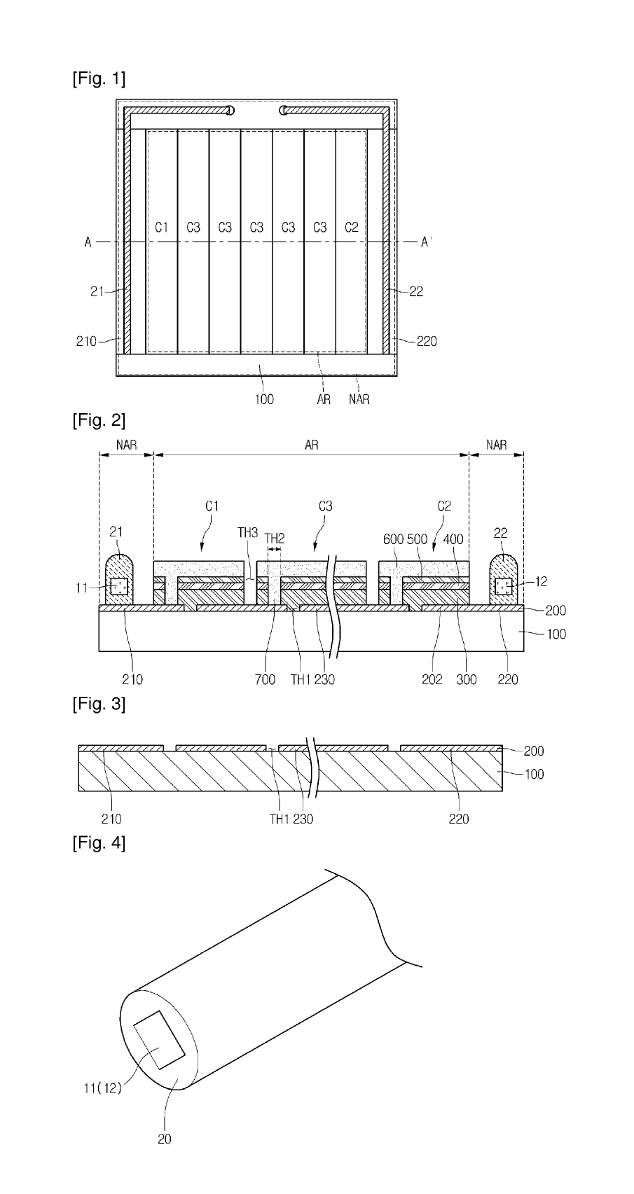

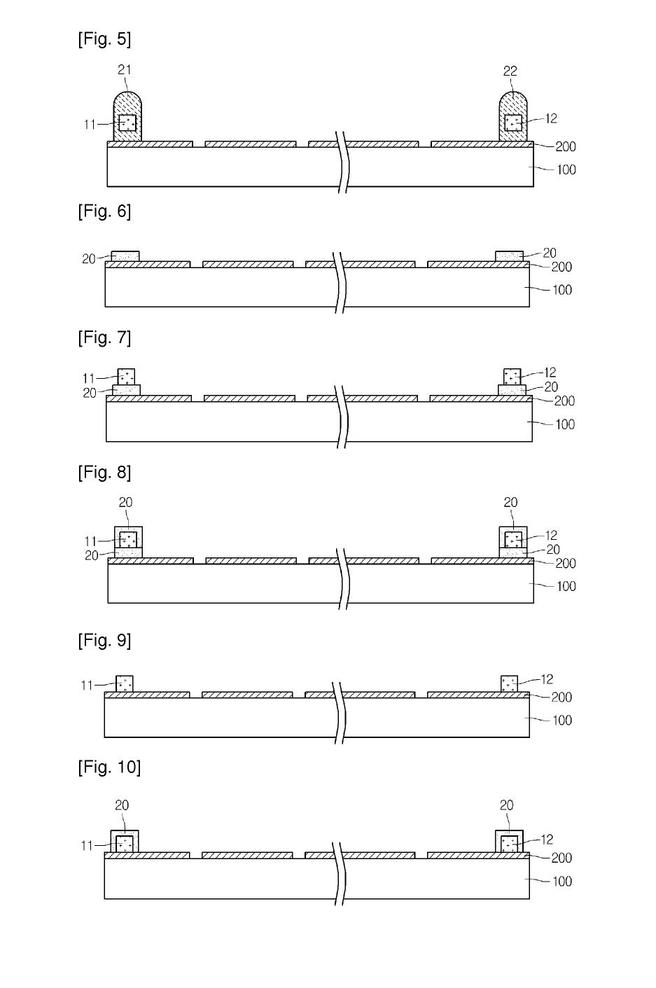

Hereinafter, a solar cell apparatus according to the embodiment will be described with reference to FIGS. 1 and 2.

FIG. 1 is a plan view showing a solar cell apparatus according to the embodiment, and FIG. 2 is a sectional view taken along line A-A′ of FIG. 1.

Referring to FIGS. .1 and 2, the solar cell apparatus according to the embodiment includes a support substrate 100, a back electrode layer 200, a first bus bar 11, a second bus bar 12, conductive parts 21 and 22, a light absorbing layer 300, a buffer layer 400, a high resistance buffer layer 500, and a window layer 600.

The support substrate 100 has a plate shape, and supports the back electrode layer 200, the first bus bar 11, the second bus bar 12, the light absorbing layer 300, the buffer layer 400, the high resistance buffer layer 500, and the window layer 600.

The support substrate 100 may include an insulator. The substrate 100 may include a glass substrate, a plastic substrate, or a metallic substrate. In more detail, the support substrate 100 may include a soda lime glass substrate. The support substrate 100 may be transparent. The substrate 10 may be rigid or flexible.

The support substrate 100 includes an active region AR and a non-active region NAR. In other words, the support substrate 100 is divided into the active region AR and the non-active region NAR.

The active region AR is defined at the central portion of the support substrate 100. The active region AR occupies the most part of the area of the support substrate 100. The solar cell apparatus according to the embodiment converts the sunlight into electrical energy at the active region AR.

The non-active region NAR surrounds the active region AR. The non-active region NAR corresponds to the outer peripheral portion of the support substrate 100. The non-active region NAR may have an area very narrower than that of the active region AR. The non-active region NAR is a region in which power is not generated.

The back electrode layer 200 is provided on the support substrate 100. The back electrode layer 200 is a conductive layer. The back electrode layer 200 may include metal such as molybdenum (Mo). The back electrode layer 200 is formed in the active region AR and the non-active region NAR.

The back electrode layer 200 may include at least two layers. In this case, the layers may include homogeneous metal or heterogeneous metals.

The back electrode 200 is provided therein with first through holes TH1. The first through holes TH1 are open regions to expose the top surface of the support substrate 100. When viewed in a plan view, the first through holes TH1 may have a shape extending in one direction.

The first through holes TH1 may have a width in the range of about 80 μm to about 200 μm. The back electrode layer 200 is divided into a plurality of back electrodes 230 and two connection electrodes 210 and 220 by the first through holes TH1. The back electrodes 230 and the first and second connection electrodes 210 and 220 are defined by the first through holes TH1. The back electrode layer 200 includes the back electrodes 230 and the first and second connection electrodes 210 and 220.

The back electrodes 230 are provided in the active region AR. The back electrodes 230 are provided in parallel to each other. The back electrodes 230 are spaced apart from each other by the first through holes TH1. The back electrodes 230 are provided in the form of a stripe.

Alternatively, the back electrodes 230 may be provided in the form of a matrix. In this case, the first through holes TH1 may be formed in the form of a lattice when viewed in a plan view.

The first and second connection electrodes 210 and 220 are provided in the non-active region NAR. In other words, the first and second connection electrodes 210 and 220 extend from the active region AR to the non-active region NAR.

In more detail, the first connection electrode 210 is connected to a window of a first cell C1. In addition, the second connection electrode 220 extends from the back electrode of a second cell C2 to the non-active region NAR. In other words, the second connection electrode 220 may be integrally formed with the back electrode 202 of the second cell C2.

The first bus bar 11 is provided in the non-active region NAR. The first bus bar 11 is provided on the back electrode layer 200. In more detail, the first bus bar 11 is provided on the first connection electrode 210. The first bus bar 11 may directly make contact with the top surface of the first connection electrode 210.

The first bus bar 11 extends in parallel to the first cell C1. The first bus bar 11 may extend to the bottom surface of the support substrate 100 through a hole formed in the support substrate 100. The first bus bar 11 is connected to the first cell C1. In more detail, the first bus bar 11 is connected to the first cell C1 through the first connection electrode 210.

The second bus bar 12 is provided in the non-active region NAR. The second bus bar 12 is provided on the back electrode layer 200. In more detail, the bus bar 12 is provided on the second connection electrode 220. The second bus bar 12 may directly make contact with the second connection bar 220.

The second bus bar 12 extends in parallel to the second cell C2. The second bus bar 12 may extend to the bottom surface of the support substrate 100 through the hole formed in the support substrate 100. The second bus bar 12 is connected to the second cell C2. In more detail, the second bus bar 12 is connected to the second cell C2 through the second connection electrode 220.

The first and second bus bars 11 and 12 face each other. In addition, the first bus bar 11 is symmetric to the second bus bar 12. The first bus bar 11 and the second bus bar 12 include conductors. The first and second bus bars 11 and 12 may include metal such as silver (Ag) representing high conductivity.

The conductive parts 21 and 22 may surround the first and second bus bars 11 and 12, respectively. The conductive parts 21 and 22 may be located on at least one of top surfaces, lateral sides, and bottom surfaces of the bus bars 11 and 12. In other words, the conductive parts 21 and 22 may surround all surfaces of the bus bars 11 and 12.

The conductive parts 21 and 22 may include carbon. For example, the conductive parts 21 and 22 may include conductive carbon.

The conductive parts 21 and 22 may be located on the bottom surfaces of the bus bars 11 and 12, so that the conductive parts 21 and 22 may make contact with the bus bars 11 and 12 and the back electrode layer 200.

In addition, the conductive parts 21 and 22 may be located on the top surface of the bus bars 11 and 12 to cover the intrinsic luster of the bus bars 11 and 12. In other words, an additional tape for covering the intrinsic luster of the bus bars 11 and 12 may be omitted.

Thereafter, although not shown in accompanying drawings, insulating parts may be additionally interposed between the bus bars 11 and 12 and the active region AR. In other words, the insulating parts may be adjacent to the bus bars 11 and 12.

The insulating parts may insulate the bus bars 11 and 12 from the active region AR. However, the embodiment is not limited thereto. In other words, the insulating units may be omitted, and the bus bars 11 and 12 may be spaced apart from the active region AR by a predetermined distance, so that the bus bars 11 and 12 may be insulated from the active region AR.

The light absorbing layer 300 is provided on the back electrode layer 200. In addition, a material constituting the light absorbing layer 300 is filled in the first through holes TH1. The light absorbing layer 300 is provided in the active region AR. In more detail, the outer peripheral portion of the light absorbing layer 300 may correspond to the outer peripheral portion of the active region AR.

The light absorbing layer 300 includes a group I-III-VI compound. For example, the light absorbing layer 300 may have a Cu(In,Ga)Se2 (CIGS) crystal structure, a Cu(In)Se2 crystal structure, or a Cu(Ga)Se2 crystal structure.

The light absorbing layer 300 has an energy bandgap in the range of about 1 eV to about 1.8 eV.

The buffer layer 400 is provided on the light absorbing layer 300. In addition, the buffer layer 400 is provided in the active region AR. The buffer layer 400 includes CdS and has an energy bandgap in the range of about 2.2 eV to about 2.4 eV.

The high resistance buffer layer 500 is provided on the buffer layer 400. In addition, the high resistance buffer layer 500 is provided in the active region AR. The high-resistance buffer layer 500 may include iZnO, which is zinc, oxide not doped with impurities. The high resistance buffer layer 500 has an energy bandgap in the range of about 3.1 eV to about 3.3 eV.

The light absorbing layer 300, the buffer layer 400, and the high resistance buffer layer 500 are formed therein with second through holes TH2. The second through holes TH2 are formed through the light absorbing layer 300. In addition, the second through holes TH2 are open regions to expose the top surface of the back electrode layer 200.

The second through holes TH2 are adjacent to the first through holes TH1. In other words, when viewed in a plan view, portions of the second through holes TH2 are formed beside the first through holes TH1.

Each second through holes TH2 may have a width in the range of about 80 μm to about 200 μm.

In addition, a plurality of light absorbing parts are defined in the light absorbing layer 300 by the second through holes TH2. In other words, the light absorbing layer 300 is divided into the light absorbing parts by the second through holes TH2.

In addition, the buffer layer 400 is divided into a plurality of buffers by the second through holes TH2. Similarly, the high resistance buffer layer 500 is divided into a plurality of high resistance buffers by the second through holes TH2.

The window layer 600 is provided on the high resistance buffer layer 500. The window layer 600 is provided in the active region AR.

The window layer 600 is transparent and a conductive layer. In addition, the resistance of the window layer 600 is higher than the resistance of the back electrode layer 200. For example, the resistance of the window layer 600 is about 100 times to 200 times greater than the resistance of the back electrode layer 200.

The window layer 600 includes oxide. For example, the window layer 600 may include zinc oxide, indium tin oxide (ITO), or indium zinc oxide (IZO).

In addition, the oxide may include conductive impurities such as aluminum (Al), alumina (Al2O3), magnesium (Mg), or gallium (Ga). In other words, the window layer 600 may include Al doped zinc oxide (AZO) or Ga doped zinc oxide (GZO). The thickness of the window layer 600 may be in the range of about 800 nm to about 1200 nm.

The light absorbing layer 300, the buffer layer 400, the high resistance buffer layer 500, and the window layer 600 are formed therein with third through holes TH3. The third through holes TH3 are open regions to expose the top surface of the back electrode layer 200. For example, the width of the third through holes TH3 may be in the range of about 80 μm to about 200 μm.

The third through holes TH3 are adjacent to the second through holes TH2. In more detail, the third through holes TH3 are formed beside the second through holes TH2. In other words, when viewed in a plan view, the third through holes TH3 are formed beside the second through holes TH2.

The window layer 600 is divided into a plurality of windows by the third through holes TH3. In other words, the windows are defined by the third through holes TH3.

The windows form a shape corresponding to that of the back electrodes 230. In other words, the windows are arranged in the form of a stripe. In addition, the windows may be arranged in the form of a matrix.

The window layer 600 includes a plurality of connection parts 700 formed by filling transparent conductive material in the second through holes TH2.

In addition, the first cell C1, the second cell C2, and a plurality of third cells C3 are defined by the third through holes TH3. In more detail, the first to third cells C1 to C3 are defined by the second through holes TH2 and the third through holes TH3. In other words, the solar cell apparatus according to the embodiment includes the first cell C1, the second cell C2, and the third cells C3 provided on the support substrate 100.

The third cells C3 are interposed between the first cell C1 and the second cell C2. The first cell C1, the second cell C2, and the third cells C3 are connected to each other in series.

The first bus bar 11 is connected to the first cell C1 through the first connection electrode 210. In more detail, the first bus bar 11 is connected to the window of the first cell C1 through the first connection electrode 210.

The second bus bar 12 is connected to the second cell C2 through the second connection electrode 220. In more detail, the second bus bar 12 is connected to the back electrode of the second cell C2 through the second connection electrode 220.

The connection parts 700 are provided inside the second through holes TH2. The connection parts 700 extend downward from the window layer 600, so that the connection parts 700 are connected to the back electrode layer 200.

Therefore, the connection parts 700 connect adjacent cells to each other. In more detail, the connection parts 700 connect windows and back electrodes, which constitute adjacent cells, to each other.

The outer peripheral portions of the light absorbing layer 300, the buffer layer 400, the high resistance buffer layer 500, and the window layer 600 may substantially match with each other. In other words, the outer peripheral portions of the light absorbing layer 300, the buffer layer 400, the high resistance buffer layer 500, and the window layer 600 may correspond to each other. In this case, the outer peripheral portions of the light absorbing layer 300, the buffer layer 400, the high resistance buffer layer 500, and the window layer 600 may match with the boundary between the active region AR and the non-active region NAR.

Accordingly, the first and second bus bars 11 and 12 are provided beside the light absorbing layer 300, the buffer layer 400, the high resistance buffer layer 500, and the window layer 600. In other words, the first and second bus bars 11 and 12 may surround the lateral sides of the light absorbing layer 300, the buffer layer 400, the high resistance buffer layer 500, and the window layer 600. In other words, the first and second bus bars 11 and 12 surround the first cell C1, the second cell C2, and the third cells C3.

In addition, the bottom surfaces of the first and second bus bars 11 and 12 are provided on the same plane as that of the bottom surface of the light absorbing layer 300. In other words, the bottom surfaces of the first and second bus bars 11 and 12 make contact with the top surface of the back electrode layer 200, and even the bottom surface of the light absorbing layer 300 makes contact with the top surface of the back electrode layer 200.

The first and second bus bars 11 and 12 may be connected to the back electrode layer 200 while directly making contact with the back electrode layer 200. In this case, the first and second bus bars 11 and 12 include metal such as silver (Ag). Similarly, the back electrode layer 200 may include metal such as molybdenum (Mo). Therefore, the contact characteristic between the first and second bus bars 11 and 12 and the back electrode layer 200 is improved.

Therefore, the contact resistance between the first bar 11 and the back electrode layer 200 and the contact resistance between the second bus bar 12 and the back electrode layer 200 are reduced, so that the solar cell apparatus according to the embodiment can represent improved electrical characteristic.

In addition, since the first bus bar 11 and the back electrode layer 200 have a high contact characteristic, and the second bus bar 12 and the back electrode layer 200 have a high contact characteristic, the first and second bus bars 11 and 12 may have a narrower area. In other words, even if the first bust bar 11 and the back electrode layer 200 make contact with each other with a small contact area, the first bus bar 11 is effectively connected to the back electrode layer 200. Similarly, even if the second bust bar 12 and the back electrode layer 200 make contact with each other with a small contact area, the second bus bar 12 is effectively connected to the back electrode layer 200

Actually, the first and second bus bars 11 and 12 do not contribute to the solar cell apparatus. As described above, according to the solar cell apparatus of the embodiment, the areas of the first bus bar 11 and the second bus bar 12, that is, areas that do not contribute to the solar power generation can be reduced.

In addition, the first and second bus bars 11 and 12 are provided in the non-active region NAR. Therefore, the solar cell apparatus according to the embodiment can more efficiently receive the sunlight as compared with a case in which the bus bars 11 and 12 are provided in the active region.

Therefore, the solar cell apparatus according to the embodiment can convert the greater quantity of the sunlight into electrical energy.

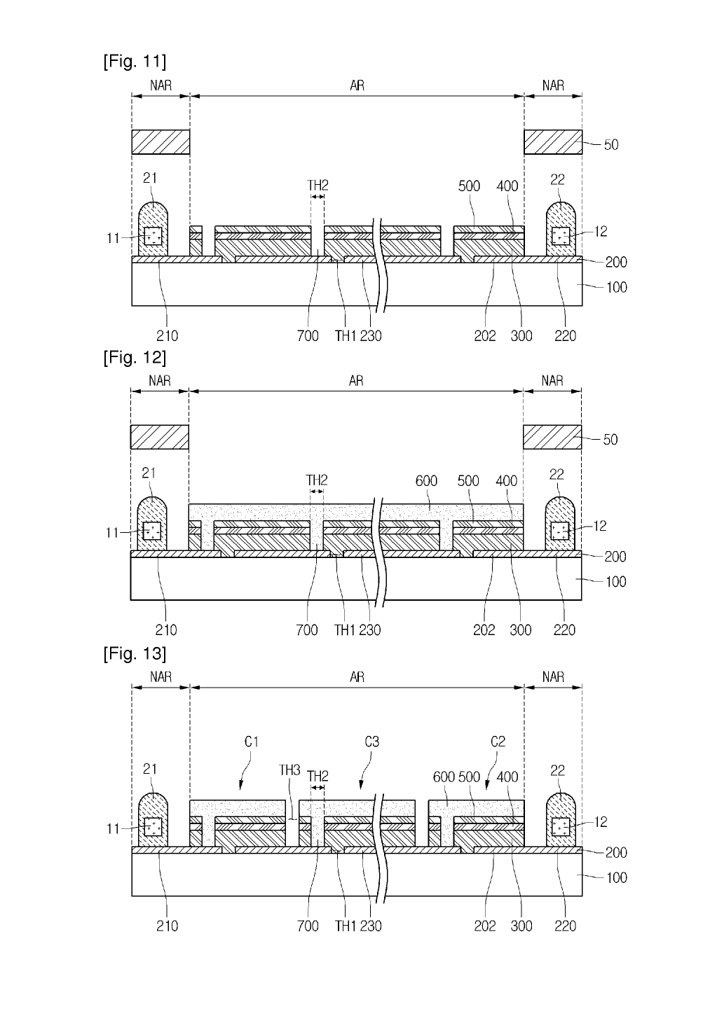

Hereinafter, a method of fabricating the solar cell apparatus according to the embodiment will be described with reference to FIGS. 3 to 13. In the following description, the method of fabricating the solar cell apparatus according to the present embodiment will be described by making reference to the description of the solar cell apparatus. In other words, the above description of the solar cell apparatus can be incorporated in the description of the method of fabricating the solar cell apparatus according to the present embodiment.

FIGS. 3 to 13 are sectional views showing the method of fabricating the solar cell apparatus according to the embodiment.

Referring to FIG. 3, the back electrode layer 200 is formed on the support substrate 100, and the first through holes TH1 are formed by patterning the back electrode layer 200. Therefore, the back electrodes 230, and the first and second connection electrodes 210 and 220 are formed on the support substrate 100. The back electrode layer 200 is patterned by a laser.

The first through holes TH1 may expose the top surface of the support substrate 100, and may have a width in the range of about 80 μm to about 200 μm.

In addition, an additional layer such as an anti-diffusion layer may be interposed between the supports substrate 100 and the back electrode layer 200. In this case, the first through holes TH1 expose the top surface of the additional layer.

Thereafter, referring to FIGS. 4 and 5, the step of forming the bus bars 11 and 12 on the back electrode layer 200 is performed. The step of forming the bus bars 11 and 12 includes a step of forming a conductive paste 20 on the bus bars 11 and 12 and a step of coating the conductive paste 20.

In the step of forming the conductive paste 20 on the bus bars 11 and 12, the bus bars 11 and 12 may be dipped into the conductive paste 20. In other words, the conductive pate 20 is provided on all surfaces of the bus bars 11 and 12 as shown in FIG. 4 by dipping the bus bars 11 and 12 into the conductive paste 20. In other words, the conductive paste 20 may surround the bus bars 11 and 12.

Thereafter, referring to FIG. 5, the conductive paste 20 surrounding the bus bars 11 and 12 may be coated. In other words, the conductive paste 20 surrounding the bus bars 11 and 12 may be provided and coated on the back electrode layer 200. For example, the conductive paste 20 may be formed through a lamination process. Thereafter, through the thermal compression, the conductive paste 20 may be bonded to the back electrode layer 200.

Meanwhile, referring to FIGS. 6 to 8, the step of forming the bus bars 11 and 12 may be subject to the following processes.

Referring to FIG. 6, the conductive paste 20 may be coated on the back electrode.

layer 200. Thereafter, referring to FIG. 7, the bus bars 11 and 12 may be located on the conductive paste 20. Referring to FIG. 8, the conductive paste 20 may be coated on the bus bars 11 and 12. Thereafter, the conductive paste 20 may be bonded to the back electrode layer 200 through the lamination and thermal compression processes.

Meanwhile, referring to FIGS. 9 and 10, the step of forming the bus bars 11 and 12 may be subject to the following processes.

Referring to FIG. 9, the bus bars 11 and 12 may be located on the back electrode layer 200. In this case, the bus bars 11 and 12 may directly adhere to the back electrode layer 200. Thereafter, referring to FIG. 10, the conductive paste 20 may be coated on the bus bars 11 and 12. Accordingly, all surfaces of the bus bars 11 and 12 may be covered except for the bottom surfaces of the bus bars 11 and 12.

Thereafter, referring to FIGS. 11 and 12, a mask 50 is provided on the support substrate 100 to cover the first and second bus bars 11 and 12.

The mask 50 covers the outer peripheral portion of the support substrate 100. The mask 50 may have a ring shape when viewed from in a plan view. The mask 50 includes a transmissive region formed at the central portion thereof.

Although the mask 50 is spaced apart from the support substrate 100 in accompanying drawings, the embodiment is not limited thereto. In other words, the mask 50 may adhere to the support substrate 100.

The active region AR and the non-active region NAR are defined by the mask 50. In other words, a portion of the mask 50 corresponding to the transmissive region corresponds to the active region AR, and a non-transmissive region having a ring shape corresponds to the non-active region NAR.

Referring to FIG. 11, the light absorbing layer 300, the buffer layer 400, and the high resistance buffer layer 500 are formed on the back electrode layer 200. The light absorbing layer 300, the buffer layer 400, and the high resistance buffer layer 500 are formed through a deposition process using the mask 50. Therefore, the light absorbing layer 300, the buffer layer 400, and the high resistance buffer layer 500 are formed in the active region AR.

The light absorbing layer 300 may be formed through a sputtering process or an evaporation scheme in the state that the mask 50 is mounted on the support substrate 100.

For example, in order to form the light absorbing layer 300, a scheme of forming a Cu(In,Ga)Se2 (CIGS) based-light absorbing layer 300 by simultaneously or separately evaporating Cu, In, Ga, and Se and a scheme of performing a selenization process after forming a metallic precursor film have been extensively performed.

Regarding the details of the selenization process after forming the metallic precursor layer, the metallic precursor layer is formed on the back contact electrode 200 through a sputtering process employing a Cu target, an In target, or a Ga target.

Thereafter, the metallic precursor layer is subject to the selenization process so that the Cu(In,Ga)Se2 (CIGS) based-light absorbing layer 300 is formed.

In addition, the sputtering process employing the Cu target, the In target, and the Ga target and the selenization process may be simultaneously performed.

In addition, a CIS or a CIG light absorbing layer 300 may be formed through a sputtering process employing only Cu and In targets or only Cu and Ga targets and the selenization process.

Thereafter, the buffer layer 400 may be formed after depositing CdS through a sputtering process or a CBD (chemical bath deposition) scheme in the state that the mask 50 is mounted.

Thereafter, in the state that the mask 50 is mounted, the high resistance buffer layer 500 is formed by depositing zinc oxide on the buffer layer 400 through a sputtering process.

The buffer layer 400 and the high resistance buffer layer 500 are deposited at a low thickness. For example, the thicknesses of the buffer layer 400 and the high resistance buffer layer may be in the range of about 1 nm to about 80 nm.

Thereafter, the second through holes TH2 are formed by removing portions of the light absorbing layer 300, the buffer layer 400, and the high resistance buffer layer 500.

The second through holes TH2 may be formed by a mechanical device such as a tip or a laser device.

For example, the light absorbing layer 300 and the buffer layer 400 may be patterned by a tip having a width of about 40 μm to about 180 μm. In addition, the second through holes TH2 may be formed by a laser having the wavelength of about 200 nm to about 600 nm.

In this case, the width of the second through holes TH2 may be in the range of about 100 μm to about 200 μm. In addition, the second through holes TH2 are formed to expose a portion of the top surface of the back electrode layer 200.

Referring to FIG. 12, in the state in which the mask 50 is mounted, the window layer 600 is formed on the light absorbing layer 300 and inside the second through holes TH2. In other words, the window layer 600 is formed by depositing a transparent conductive material on the high resistance buffer layer 500 and inside the second through holes TH2.

In this case, after filling the transparent conductive material inside the second through holes TH2, the window layer 600 directly makes contact with the back electrode layer 200.

Referring to FIG. 13, the mask 50 is removed, and the third through holes TH3 are formed by removing portions of the light absorbing layer 300, the buffer layer 400, the high resistance buffer layer 500, and the window layer 600. Accordingly, the window layer 600 is patterned to define a plurality of windows, the first cell C1, the second cell C2, and the third cells C3. The width of the third, through holes TH3 may be in the range of about 80 μm to about 200 μm.

As described above, the solar cell apparatus according to the embodiment is formed. The first and second bus bars 11 and 12 are formed prior to the light absorbing layer 300 such that the first and second bus bars 11 and 12 are connected to the back electrode layer 200. Accordingly, the solar cell apparatus according to the embodiment may represent high photoelectric conversion efficiency with an improved electrical characteristic.

In addition, according to the embodiment, the manufacturing cost can be reduced because the soldering process to bond the bus bars 11 and 12 can be omitted. In addition, the processes to cover the intrinsic luster of the bus bars 11 and 12 can be omitted, so that the process time can be saved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a substrate;
a back electrode layer on the substrate;
a light absorbing layer on the back electrode layer;
a front electrode layer on the light absorbing layer;
a bus bar provided beside the light absorbing layer while being connected to the back electrode layer; and
a conductive part surrounding the bus bar.

2. The solar cell apparatus of claim 1, wherein the conductive part is located on a top surface of the bus bar.

3. The solar cell apparatus of claim 1, wherein the conductive part includes carbon.

4. The solar cell apparatus of claim 3, wherein the conductive part includes conductive carbon.

5. The solar cell apparatus of claim 1, wherein the conductive part surrounds all surfaces of the bus bar.

6. The solar cell apparatus of claim 1, wherein the substrate includes a non-active region corresponding to an outer peripheral portion of the substrate; and an active region inside the non-active region, and wherein the bus bar is provided in the non-active region, and the light absorbing layer and the front electrode layer are provided in the active region.

7. The solar cell apparatus of claim 1, wherein a bottom surface of the light absorbing layer is aligned in line with a bottom surface of the bus bar.

8. The solar cell apparatus of claim 1, wherein the bus bar directly makes contact with the back electrode layer.

9. The solar cell apparatus of claim 6, further comprising an insulating part disposed between the bus bar and the active region.

10-14. (canceled)

15. The solar cell apparatus of claim 2, wherein the conductive part covers an intrinsic luster of the bus bar.

16. The solar cell apparatus of claim 1, wherein the conductive part is located on a lateral side of the bus bar.

17. The solar cell apparatus of claim 1, wherein the conductive part makes contact with the bus bar and the back electrode layer.

18. The solar cell apparatus of claim 1, wherein the conductive part is located on a bottom surface of the bus bar.

19. The solar cell apparatus of claim 18, wherein the bus bar is spaced apart from the active region by a predetermined distance.

20. The solar cell apparatus of claim 1, wherein the back electrode is provided therein with a first through hole.

21. The solar cell apparatus of claim 20, wherein the first through hole is open region to expose a top surface of the support substrate.

22. The solar cell apparatus of claim 1, wherein the bus bar is spaced apart from the back electrode layer.

23. The solar cell apparatus of claim 1, wherein the bus bar is not exposed through the conductive part.

24. The solar cell apparatus of claim 1, wherein a bottom surface of the bus bar is higher than a top surface of the back electrode layer.

25. The solar cell apparatus of claim 1, further comprising a window layer on the front electrode, and
wherein a top surface of the conductive part is higher than a top surface of the window layer.
